(19) United States
(12) Patent Application Publication
(10) Pub. No.: US 2019/0180931 A1
(43) Pub. Date: Jun. 13, 2019

(54) INDUCTOR LAYOUT HAVING IMPROVED ISOLATION THROUGH BLOCKING OF COUPLING BETWEEN INDUCTORS, AND INTEGRATED CIRCUIT DEVICE USING SAME

(71) Applicants: Korea Advanced Institute of Science and Technology, Daejeon (KR); Research & Business Foundation Sungkyunkwan University, Suwon-si (KR)

(72) Inventors: Hyung-joun Yoo, Daejeon (KR); Sang-sun Yoo, Daejeon (KR); Kang-yoon Lee, Suwon-si (KR)

(73) Assignees: Korea Advanced Institute of Science and Technology, Daejeon (KR); Research & Business Foundation Sungkyunkwan University, Suwon-si (KR)

(21) Appl. No.: 16/304,910

(22) PCT Filed: Feb. 23, 2017
(86) PCT No.: PCT/KR2017/002006

§ 371 Date: Nov. 27, 2018

(30) Foreign Application Priority Data
Jun. 1, 2016 (KR) 10-2016-0068260

(51) Int. Cl. H01F 27/36; H01F 27/28; H04B 5/00; H01F 38/14; H01L 23/522; H01L 49/02

(52) U.S. Cl. CPC H01F 27/365; H01F 27/2804; H01L 28/10; H01F 38/14; H01L 23/5227; H04B 5/0075

(57) ABSTRACT

Disclosed are an inductor layout and an integrated circuit device with improved isolation between inductors through shielding magnetic coupling between the inductors. first and second inductor coils are horizontally spaced apart from each other. A conductor loop is disposed in parallel above the first inductor coil and shields magnetic coupling between the first and second inductor coils in the manner that a part of magnetic flux of a first time-varying magnetic field generated by the second inductor coil is cancelled by magnetic flux of a second magnetic field generated by an induction current that flows in the conductor loop magnetically interlinked with the first time-varying magnetic field. The inductor layout can be applied to an RFIC device to reduce magnetic coupling between inductors of a power amplifier and an oscillator. Improved performance of the device and a very small RFIC can be achieved.

### CROSS-REFERENCE TO RELATED APPLICATION

This application claims priority under 35 USC § 119 to Korean Patent Application No. 10-2016-0068260, filed on Jun. 1, 2016 in the Korean Intellectual Property Office (KIPO), the contents of which are herein incorporated by reference in their entirety.

### BACKGROUND

### 1. Technical Field

The present invention relates to a technology for reducing coupling between magnetic inductors to improve isolation therebetween, and more particularly, to a technology for protecting an inductor from an external magnetic field in a small integrated circuit (IC) device, such as a radio frequency integrated circuit (RFIC), including an inductor, thereby miniaturizing the IC device as well as improving signal processing performance of the IC device.

### 2. Description of the Related Art

For RFICs, which are used primarily in radar and wireless communications, an issue of magnetic field coupling between inductors is an old problem. The magnetic field coupling mainly through the substrate has been a problem, and a lot of researches on the issue have been carried out. Previously, the size of the RFIC was relatively large and a sufficient distance between the inductors could be provided, so that the coupling by the magnetic field inside the chip could be avoided to some extent.

Recently, in order to meet the need of high-speed data transmission in mobile communication, a carrier aggregation (CA) technology has been developed in which several different frequency bands are bundled to speed up as one frequency. With the CA technology, it became possible to simultaneously transmit and receive signals of various frequency bands. For example, a LTE-A communication method uses the CA technology as a key element. In order to simultaneously process signals of various frequency bands, a large number of radio frequency (RF) paths are required, and a large number of power amplifiers (PA) and oscillators should simultaneously operate inevitably. As a result, the magnetic coupling issue became a practical problem.

In addition, with the recent development of mobile devices and increase of interests in bio, healthcare, and the like, there is an increasing demand for ultra-small and low-power devices. Due to the development of process technology therefor, for example, the gate length of a CMOS process is reduced so that the RFIC can also be made in a smaller size than before. However, as an area of the RFIC becomes smaller, the distance between blocks of the RFIC becomes closer, and an issue of isolation between them newly emerges. That is, since the distance between the inductors provided in each block is getting closer, the magnetic coupling issue between the inductors is further accelerated. For example, the inter-inductor magnetic coupling between a PA transmitting a high output and an LC oscillator producing a carrier frequency in the RFIC serves as a factor to deteriorate the performance of the RFIC. In addition, not only conventional voltage controlled oscillators (VCOs) but also digitally controlled oscillators (DCOs), which are actively used recently, have the problem of magnetic coupling between inductors.

### SUMMARY

In order to solve these problems, it is an object of the present invention to provide an inductor layout capable of increasing the magnetic coupling isolation per unit separation distance between inductors, thereby reducing a degree of magnetic field coupling between the inductors.

It is another object of the present invention to provide an IC device that can be realized in a ultra-small size and improve overall performance by adopting the inductor layout and arranging blocks including inductors at a close distance from each other.

According to embodiments of the present invention for accomplishing the above objects, there is provided an inductor layout with improved isolation between inductors through shielding the magnetic coupling between the inductors. The inductor layout includes an inductor coil and a conductor loop. The conductor loop is disposed over the inductor coil, and configured to shield magnetic coupling between the inductor coil and a first time-varying magnetic field directed to the inductor coil from a peripheral magnetic field source such that at least a part of magnetic flux of the first time-varying magnetic field is cancelled by magnetic flux of a second magnetic field generated by an induction current that flows in the conductor loop which is magnetically interlinked with the magnetic flux of the first time-varying magnetic field. A direction of an induced electromotive force for causing the induction current to flow is a direction that interferes with the change of the magnetic flux of the first time-varying magnetic field.

In an exemplary embodiment of the inductor layout, the conductor loop may be disposed so as to surround a circumference of the inductor coil when viewed in a direction normal to the inductor coil.

In an exemplary embodiment of the inductor layout, the conductor loop may include a loop switching unit as a part of an entire section of the conductor loop. The loop switching unit may include a switch element and a resistor, which is connected to the switch element in parallel to each other, configured to block the flow of the induction current, and control a function of shielding the magnetic coupling by the conductor loop for the inductor coil to be activated or deactivated as the switch element is turned on or off.

In an exemplary embodiment of the inductor layout, the conductor loop may be made of a conductor pad or a conductor coil being wound a plurality of turns.

In an exemplary embodiment of the inductor layout, the inductor coil may be a spiral coil or a ring coil.

Meanwhile, an IC device according to other embodiments of the present invention is provided. The IC device includes a first inductor coil, a second inductor coil, and a conductor loop. The second inductor coil is spaced apart in a horizontal direction around the first inductor coil. The conductor loop is disposed over the first inductor coil, and configured to shield magnetic coupling between the first inductor coil and the second inductor coil such that at least a part of magnetic flux of a first time-varying magnetic field generated by the second inductor coil is cancelled by magnetic flux of a second magnetic field generated by an induction current that flows in the conductor loop which is magnetically interlinked with the magnetic flux of the first time-varying magnetic field.

In an exemplary embodiment of the IC device, the conductor loop may include a loop switching unit as a part of an entire section of the conductor loop. The loop switching unit may include a switch element and a resistor, which is connected to the switch element in parallel to each other, configured to block the flow of the induction current, and control a function of shielding the magnetic coupling by the conductor loop for the inductor coil to be activated or deactivated as the switch element is turned on or off.

In an exemplary embodiment of the IC device, the IC device may be a RFIC device.

In an exemplary embodiment of the IC device, the first inductor coil may be an inductor for a power amplifier, and the second inductor coil may be an inductor for an oscillator.

Thus, in a small IC device constituting a wireless transmitter, a wireless receiver, or a wireless transceiver, disposing the conductor loop for shielding the magnetic coupling over the inductors can protect the inductors from being interfered with the external magnetic field by shielding the magnetic field coupling between the inductors.

According to the present invention, the inductors can be disposed closer to each other while the degree of magnetic coupling per unit separation distance between the inductors is kept the same as the conventional one. Therefore, it is possible to reduce the area of the IC device such as an RFIC chip employing such an inductor layout, and to miniaturize a chip. Since the inductors are freed from the magnetic field coupling and can be arranged closer to each other than the conventional method, the cost competitiveness of the IC (for example, the RFIC chip) chip installed with the inductors together can be increased.

Also, according to the present invention, when the inductors are arranged at the same distance as the conventional ones, the amount of magnetic field coupling is greatly reduced compared with the conventional one, and thus an inductor-mounted IC with superior performance can be realized. In another aspect, an IC (e.g., an RFIC chip) that is competitive in terms of performance can be implemented because it is possible to integrate a calibration circuit or other circuits that can increase reliability by reducing wasted space.

### BRIEF DESCRIPTION OF THE DRAWINGS

Illustrative, non-limiting example embodiments will be more clearly understood from the following detailed description taken in conjunction with the accompanying drawings.

FIG. 1 is a view for showing a problematic situation to be solved by the present invention.

FIG. 2 is a layout diagram for widening a space between inductors in order to avoid the problematic magnetic coupling.

FIG. 3 is a three-dimensional view of an inductor coil layout with improved isolation by adding a conductor loop for coupling-shield over a general inductor coil, according to a first embodiment of the present invention.

FIG. 4 is a conceptual diagram (a planar layout) for describing a basic operation principle related to the magnetic coupling-shield by the conductor loop against the inductor coils shown in FIG. 3.

FIG. 5 illustrates a planar layout in which an inductor coil is configured so as to activate or deactivate a magnetic coupling-shield function of a conductor loop selectively as needed by using a switch element, according to a second embodiment of the present invention.

FIG. 6 is a graph showing a change in isolation characteristic between inductors according to the types of conductors constituting the conductor loop.

FIG. 7 is a graph showing a change in isolation degree according to a width of the conductor loop.

FIG. 8 is a graph showing a change in isolation degree according to a width of a switch of a loop switching unit.

### DETAILED DESCRIPTION OF THE EMBODIMENTS

The specific structural and functional descriptions of the embodiments of the present inventive concept disclosed herein are merely illustrative for the purpose of describing embodiments of the present inventive concept. Embodiments of the present inventive concept may be embodied in various forms and should not be construed as limited to the embodiments set forth herein.

The present inventive concept can be variously modified and can take various forms. Specific embodiments are illustrated in the drawings and described in detail herein. It should be understood, however, that the present inventive concept is not intended to be limited to the particular forms disclosed, but includes all modifications, equivalents, and alternatives falling within the spirit and scope of the present inventive concept.

It will be understood that, although the terms first, second, third etc. may be used herein to describe various elements, these elements should not be limited by these terms. These terms are used to distinguish one element from another. Thus, a first element discussed below could be termed a second element without departing from the teachings of the present inventive concept, and similarly the second element could be termed the first element.

It will be understood that when an element is referred to as being “connected” or “coupled” to another element, it may be directly connected or coupled to the other element or any intervening element may be present. In contrast, when an element is referred to as being “directly connected” or “directly coupled” to another element, there is no intervening element present. Other words used to describe the relationship between elements should be interpreted in a like fashion (e.g., “between” versus “directly between,” “adjacent” versus “directly adjacent,” etc.).

The terminology used herein is for the purpose of describing particular example embodiments only and is not intended to be limiting of the present inventive concept. As used herein, the singular forms “a,” “an” and “the” are intended to include the plural forms as well, unless the context clearly indicates otherwise. It will be further understood that the terms “comprise”, “have,” and the like used in this specification, specify the presence of stated features, integers, steps, operations, elements, and/or components, but do not preclude the presence or addition of one or more other features, numbers, steps, operations, elements, components, and/or combinations thereof.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, detailed descriptions of the present inventive concept will be given so as to easily carry out it with reference to the accompanying drawings.

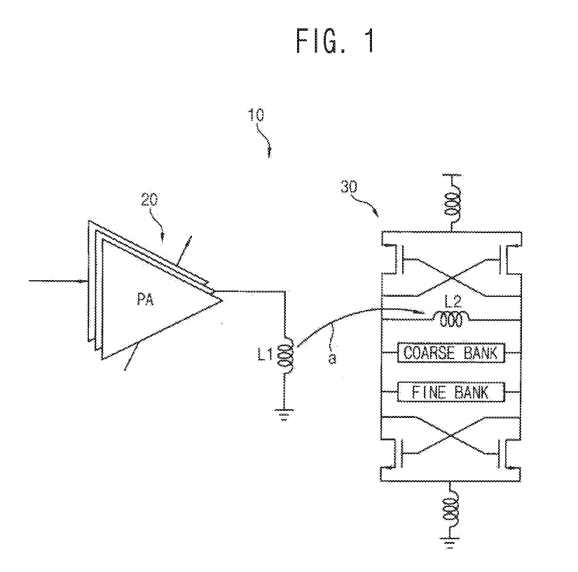

For example, considered are a PA in which an inductor coil is provided and an RF transceiver or an RFIC chip having oscillators. FIG. 1 shows a situation in question within the RFIC chip. Being in charge of transmitting a large signal, a transmitter 10 transmits the large signal at a strong power so as to transfer the radio frequency (RF) signal to far away. At this time, an oscillator 30 plays the role of making the transmission frequency. In the transmitter 10, a drive amplifier (DA) or a power amplifier (PA) 20 transmits a large power through an inductor L1. The oscillator 30 also produces a transmit frequency through an inductor L2. At this time, magnetic coupling occurs between the inductor L1 of the PA 20 and the inductor L2 of the oscillator 30, which may adversely affect the oscillator 30.

Alternatively, the 8-shaped inductor, which is much larger than a typical inductor, may be used to solve the magnetic coupling issue. However, this method has the following disadvantages. That is, the size of the 8-type inductor is bigger than that of a typical inductor, and its Q factor is bad, which may slightly increase the power consumption. Also, in the vertical direction, there is no increase in isolation. In particular, the 8-shaped inductor can only be used for a single-turn spiral inductor and cannot be used for spiral inductors with more than 2 turns. In other words, it can only be used in RFICs with small inductor values and cannot be used in applications that require large inductor values. The 8-shaped inductor may not be suitable for low-power RFICs because large inductor values must be selected for low-power operations.

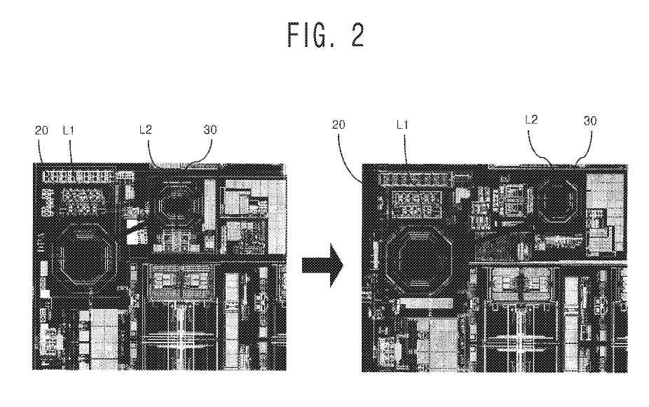

In order to avoid magnetic field coupling between the inductors, an inductor of the PA and an inductor of the oscillator may be arranged as far as possible so that the magnetic field coupling between them can be reduced. FIG. 2 shows an example of such a design. The inductor layout shown is to avoid the magnetic field coupling between them by spacing the inductors L1 and L2 that are in trouble. However, since this layout is against the demand for miniaturization of the RFIC chip, the layout cannot be an ultimate solution. If the distance is further increased, the size of the chip must be increased, which may weaken the price competitiveness. Therefore, there is a limit to further increasing the spacing between the inductors. In order to secure the distance between the inductors within the limit, it may be possible to consider a way of changing the direction of the oscillator to increase the distance. However, it is difficult to completely solve the magnetic field coupling problem.

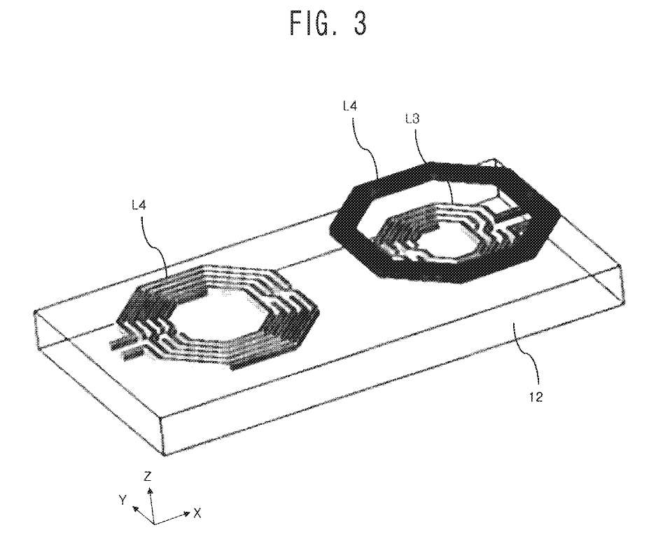

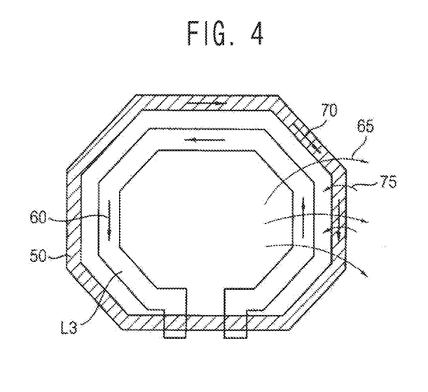

FIG. 3 schematically illustrates an embodiment of an inductor coil layout according to the present inventive concept. According to this layout, a conductor loop 50 for magnetic coupling-shield is added to reduce the magnetic field coupling between the inductor coils L3 and IA. FIG. 4 is a conceptual diagram (a planar layout) for describing a basic operation principle related to the magnetic coupling-shield by the conductor loop against the inductor coils L3 and IA in the inductor coil layout of FIG. 3.

It can be seen that only the elements related to the implementation of the present inventive concept among the elements of the RFIC chip are selectively shown in FIG. 3. The first inductor coil L3 is mounted on a circuit board 12 parallel to the xy-plane. The conductor loop 50 for magnetic coupling-shield is further disposed over the first inductor coil L3.

The difference in height between the first inductor coil L3 and the conductor loop 50 may vary from about 1 to several micrometers (μm), depending on the application. The conductor loop 50 may be arranged in parallel with the xy-plane like the first inductor coil L3.

The conductor loop 50 may be preferably disposed so as to surround the first inductor coil L3 when viewed in the direction normal to the first inductor coil L3 (i.e., the z-direction in FIG. 3). That is, a diameter of the conductor loop 50 may be preferably larger than a diameter of the first inductor coil L3. If the diameter of the conductor loop 50 is substantially equal to the diameter of the first inductor coil L3 and overlaps each other when viewed in the z-direction, a capacitor component (capacitance) between them may become large, which may degrade performance. If the diameter of the conductor loop 50 is smaller than that of the first inductor coil L3 and the conductor loop 50 is arranged to be enclosed by the first inductor coil L3, an effect of shielding the magnetic field coupling becomes insignificant. The conductor loop 50 and the first inductor coil L3 may be in the form of a ring or a closed loop substantially centered on each other. The shape of the closed loop may be various shapes such as a circle, an ellipse, a polygon, and the like.

The conductor loop 50 may be made of a metal or other conductive material having excellent conductivity. When formed as a component of an IC, the conductor loop 50 may be embodied as a metal pad, for example. The metal pad may be made of a metal having good conductivity, such as aluminum or copper. The conductor loop 50 may also be embodied as a conductor coil wound with a plurality of turns.

For example, in the RFIC chip, the conductor loop 50 may be implemented with a metal that is higher than the inductor coil L3. In general, an inductor requires a high quality factor, which requires low resistance. For this reason, the inductor coil L3 may be designed with an ultra-thick metal (UTM). The UTM is the thickest metal of any metal and has a very low sheet resistance. The metal positioned above the UTM is only an aluminum (Al) pad layer. Therefore, if the Al pad layer is used to make the conductor loop 50, the conductor loop 50 can be placed above the inductor coil L3. An insulating layer may be disposed between the inductor coil L3 and the conductor loop 50. Without being grounded, the conductor loop 50 may be provided in a stacked form over the insulating layer such as a silicon oxide layer.

On the substrate 12, the second inductor coil L4 may be further provided around the first inductor coil L3. The first inductor coil L3 may be, for example, an inductor coil of the oscillator 30, and the second inductor coil L4 may be, for example, an inductor coil of the PA.

The first and second inductor coils L3 and L4 may be, for example, spiral or ring-shaped. The two inductor coils L3 and L4 may be made of metal or other conductive material having excellent conductivity.

As illustrated in FIGS. 3 and 4, if a loop or ring is made of, for example, a metal pad over the first inductor coil L3 of the oscillator 30, then magnetic coupling of the first inductor coil L3 with other inductor coils, for example, the second inductor coil L4, may be reduced so that the degree of isolation between the two inductor coils L3 and L4 can be increased.

The principle of achieving such effects will be described below in more detail. When a current 60 for oscillation flows in the first inductor coil L3 in a counterclockwise direction, for example, during the oscillator 30 operates, a time-varying magnetic field 65 is generated as shown in FIG. 4. This time-varying magnetic field 65 passes through the conductor loop 50 for magnetic coupling-shield so that an induced current flows through the conductor loop 50 in accordance with Lenz's law. At this time, a magnetic field 75 due to the induced current is generated in the conductor loop 50. Since a direction of the magnetic field 65 generated by the first inductor coil L3 of the oscillator 30 and a direction of the magnetic field 75 generated by the induced current 70 of the conductor loop 50 are opposite to each other, the magnetic field 75 cancels the magnetic field 65. That is, the total amount of the magnetic field that is effectively radiated from the first inductor coil L3 of the oscillator 30 decreases by the amount of offset due to the magnetic field 75 generated by the induced current 70.

The magnetic field coupling between the inductors may be represented by mutual inductance. When the mutual inductance from the PA 20 to the oscillator 30 is referred to M₂₁ and the mutual inductance from the oscillator 30 to the PA 20 is referred to M₁₂, a relationship of M₂₁=M₁₂ is established. That is, in FIG. 4 the effect that the amount of magnetic flux radiated from the first inductor coil L3 of the oscillator 30 is reduced means that the amount of the magnetic flux entering the first inductor coil L3 of the oscillator 30 is also reduced. When the present invention is applied to the first inductor coil L3 of the oscillator 30, the amount of magnetic field coupling from the first inductor coil L3 of the oscillator 30 to the second inductor coil L4 of the PA 20 is reduced. In the same manner, the amount of magnetic field coupling from the second inductor coil L4 of the PA 20 to the first inductor coil L3 of the oscillator 30 is also reduced.

More specifically describing, the magnetic coupling between the inductors is equal to the amount of mutual inductance, which is proportional to the magnetic field. The magnetic flux is a value obtained by integrating the magnitude of the magnetic field with respect to the area as shown in equation (1).

ϕ_{B}=∫_{A}\vec{B}·d\vec{A} (1)

However, it is not easy to calculate the closed loop magnetic field vector generated in the helical inductor coil L3. Therefore, assuming that the inductor coil L3 is a simple magnetic dipole and the magnetic flux density B is calculated as Equation (2).

$$B ( \vec{s} , λ ) = \frac{{μ}_{\vec{0 m}}}{4 π {s}^{3}} \sqrt{1 + 3 {sin}^{2}} λ \qquad ( 2 )$$

Here, s is a displacement vector, λ is a magnetic latitude, and m is a magnetic dipole moment. Since the two inductor coils L3 and L4A in the RFIC chip are substantially in the same plane, the magnetic latitude λ is 0 degree, which makes calculation easy. Consequently, the mutual inductance between the two inductor coils L3 and L4 is a function of inner radius r of the inductors, and the displacement vector s, and can be approximated as Equation (3).

$${M}_{21} \approx \frac{{μ}_{0} π {r}_{1}^{2} {r}_{2}^{2}}{4 {s}^{3}} = \frac{{μ}_{0} π {r}^{4}}{4 {s}^{3}} \qquad ( 3 )$$

Equation (3) implies that the mutual inductance must be reduced in order to reduce magnetic field coupling between the two inductor coils L3 and L4. In addition, Equation (3) thus implies that in order to reduce the mutual inductance, it is necessary to reduce the inner radius r of the inductor coils or increase the separation distance s between the inductors. Since the size of the inner radius r of the inductor coils is be determined according to the required inductance value, the separation distance s between the inductor coils L3 and L4 should be increased. However, this approach may suffer from practical limitations due to limitations on chip size.

When a closed conductor loop 50 is formed in the first time-variant magnetic field B that varies with time, an induced current is generated in the conductor loop 50 in a direction that interferes with the magnetic flux change of the first time-variant magnetic field (B) 65 generated in accordance with the change of external current, and the first time-varying magnetic field (B) 65 is canceled by the second magnetic field 75 due to the induced current. When the closed conductor loop 50 is formed on the inductor coil L3, the amount of magnetic flux of the first time-varying magnetic field (B) 65 is reduced and the isolation between the inductors L3 and LA is increased. At this time, a degree of the isolation may vary depending on which conductive material or the kind of metal is used as the conductor loop 50. In addition, the isolation characteristics may vary depending on a designed width of the conductor loop 50. The performance of the inductor coil L3 may be also changed depending on the kind of material of and the width of the conductor loop 50 for magnetic field coupling-shield, which may lead to performance deterioration.

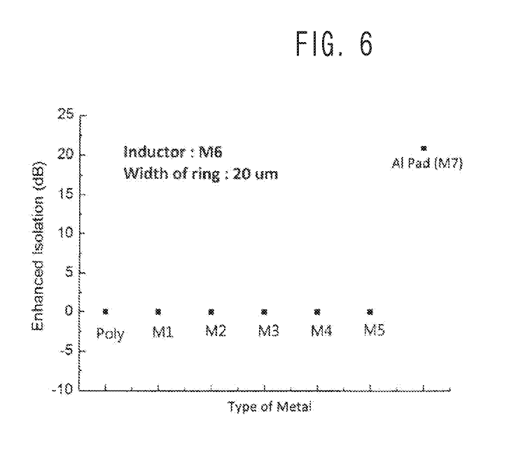

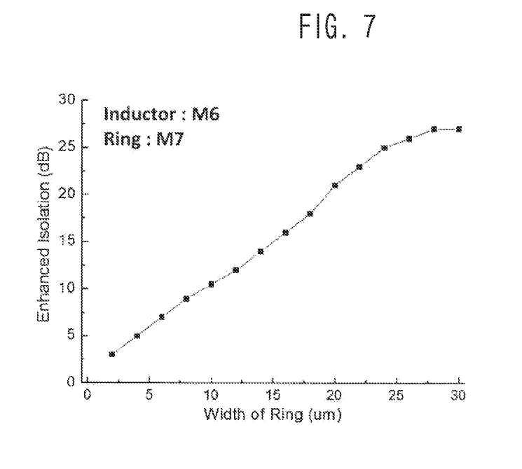

The graphs of FIGS. 6 and 7 respectively show simulation results comparing the isolation degrees between the following two cases when the two conductor coils are spaced apart by 200 μm: a first case is that the conductor loop 50 is provided over one inductor coil, and a second case that the conductor loop 50 are not provided.

According to FIG. 6, it can be seen that when the inductor coil is made of, for example, M6 metal and the conductor loop 50 is positioned below the M6 (toward the substrate), there is no gain for isolation even if an induced current flows in the conductor loop 50. On the contrary, it can be seen that when the conductor loop 50 is implemented using the metal M7 above the inductor coil, it can have an isolation gain of about 21 dB. It can be seen that there is no additional magnetic field reduction since a significant portion of the magnetic field is canceled by the already mirrored image current on the substrate side, and the magnetic coupling on the air interface side is predominant.

The graph of FIG. 7 shows an increase in the isolation degree according to the width of the conductor loop 50 when the conductor loop 50 for magnetic coupling-shield is implemented with the metal M7. As the width of the conductor loop 50 increases, the resistance of the conductor loop 50 itself decreases, so that the amount of the induced current increases, and the magnetic field decreases. Therefore, it can be seen that the isolation characteristic is improved. At this time, since an effective inductance value decreases, it is preferable to determine the optimal value considering the change in performance of the inductor coil.

When the conductor loop 50 is formed over the inductor coil L3 and the induced current is allowed to flow through the conductor loop 50, the effective magnetic field generated by the inductor coil L3 is reduced, which results in an effect of substantially decreasing the effective inductance. If the inductor coil L3 constitutes a part of the oscillator 30, the performance of the oscillator 30 may be affected. However, by minimizing the resistance by making the conductor loop 50 thick and wide and minimizing the parasitic capacitance between the conductor loop 50 and the inductor coil L3. The magnetic field coupling effect can be reduced while minimizing the deterioration of the performance of the oscillator inductor coil (L3). Since forming the conductor loop 50 below the inductor coil L3 does not help to reduce the amount of magnetic field coupling, it is necessary to provide the conductor loop 50 above the inductor.

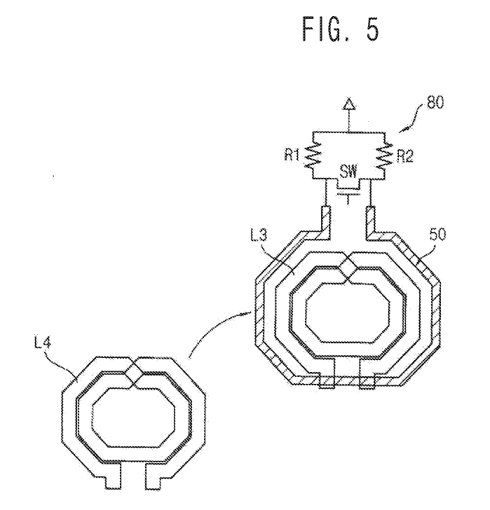

Next, FIG. 5 shows a planar layout of the inductor coil according to the second embodiment of the present invention. The second embodiment discloses a structure in which a function of shielding the magnetic field coupling of the conductor loop can be activated or deactivated as required by using a switch element.

The second embodiment is different from the first embodiment in that a part of the entire section of the conductor loop 50 is constituted by a loop switching unit 80. The loop switching unit 80 may include resistive elements R1 and R2 for suppressing a flow of the induced current, and a switch element SW connected in parallel to the resistive elements R1 and R2. The conductor (e.g., metal) pad section may occupy most of the conductor loop 50 and the remaining section may be the loop switching unit 80. The conductor pad section and the loop switching unit 80 are electrically connected to each other. The resistive elements R1 and R2 have a resistance value large enough to suppress the flow of the induced current that may be generated in the conductor loop 50 by the magnetic field introduced from the outside. Although the two resistive elements are shown in the drawing, the number of resistive elements may be one or three or more. The switch element SW may be an element whose turn-on and turn-off can be controlled by a switching control signal, and may be implemented with a transistor element such as a MOSFET or the like.

When the switch element SW is turned on, the conductor pad section of the conductor loop 50 and the loop switching unit 80 can form a closed loop. At this time, the magnetic coupling shielding function of the conductor loop 50 with respect to the inductor coil L3 is activated. On the other hand, when the switch element SW is turned off, the resistive elements R1 and R2 of the loop switching unit 80 are connected to the conductor pad section of the conductor loop 50. However, the resistance value of the resistive elements R1 and R2 is sufficiently large, so that even if the magnetic flux passes through the conductor loop 50, it may be difficult for the induced current to flow through the conductor loop 50. Therefore, while the switch element SW is turned off, the magnetic coupling shielding function for the inductor coil L3 of the conductor loop 50 is inactivated. Therefore, through the ON/OFF control of the switch element SW of the loop switching unit 80, the magnetic field coupling shielding function of the conductor loop 50 may be or may not be utilized as needed.

When the PA 20 outputs a large power, the fully closed conductor loop 50 can be formed by controlling the switch element SW to be turned on. Thereby, the conductor loop 50 can provide the magnetic field coupling shielding function for the inductor coil L3 of the oscillator 30. Thereby, an effect of reducing the magnetic field coupling between the inductors L3 and LA appears. Alternatively, when the PA 20 uses a small power, the amount of magnetic field coupling between the inductor coils is small. Therefore, it is not necessarily required to use the magnetic field coupling shielding function of the conductor loop 50. At this time, the switch SW may be turned off. Then, the conductor loop 50 may be formed to include the resistive elements R1 and R2 having a very large resistance value to such an extent that a part section of the conductor loop 50 can prevent the flow of the induced current. Therefore, the effect that the conductor loop 50 is not formed appears, and it the original oscillator 30 can be used without the magnetic field coupling shielding function of the conductor loop 50 being activated.

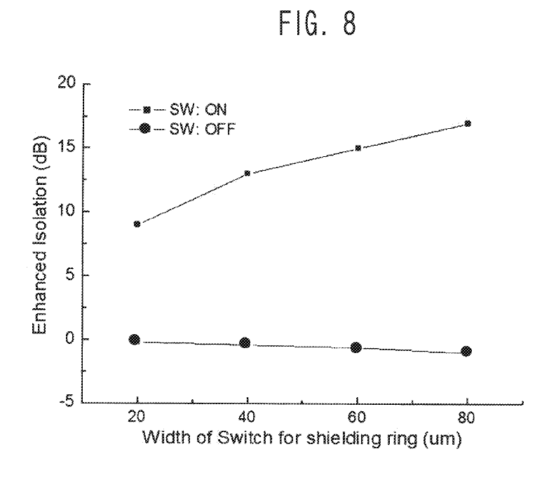

FIG. 8 is a graph showing a change in isolation degree according to a width of a switch of a loop switching unit. When using the loop switching unit 80 is used, the degree of magnetic field coupling between the inductor coils may vary depending on the size of the switch element SW of the loop switching unit 80. With reference to FIG. 8, the observed isolation characteristic according to the size of the switch element says that a turn-on resistance of the switch element SW becomes smaller as the size of the switch element SW becomes larger. Therefore, it can be seen that when the switch element SW is turned on, the isolation characteristic are improved. It can be seen that when the switch element SW is turned off, the isolation characteristic is slightly deteriorated as compared with the case where the conductor loop 50 is not provided. However, this may not be a practical problem because the performance degradation is less than 1 dB. It is desirable to find and apply the optimum point to apply the conductor loop 50 for the magnetic coupling-shield to the oscillator without degrading the performance while reducing the amount of magnetic field coupling.

As described above, the second embodiment is an efficient method which can selectively utilize the magnetic field coupling shielding function through ON/OFF control of the switch element SW of the loop switching unit 80. When the conductor loop 50 is formed, the power consumption can be slightly increased. If ultra-low power is required, the power consumption can be controlled by the method shown in FIG. 5.

Actually, when forming an inductor coil on a chip, a guide ring (not shown) may be surrounded around the inductor coil to protect the magnetic field. It is not to allow other metals or active components to enter into it. Normally, the guide ring is installed at an interval of about 40 μm from the inductor coil. Therefore, if the conductor loop for shielding the magnetic coupling is disposed inside the guard ring of the inductor coil, the amount of magnetic coupling can be efficiently reduced without increasing the chip area.

The magnetic coupling reduction amount varies depending on the distance between the inductors. However, at a distance of 200 μm or less, the isolation gain of 21 dB (that is, about 100 times decrease) of the magnetic coupling amount can be obtained. This can be seen by simulation and measurement. It can be also confirmed that the reduction of the magnetic coupling amount is determined depending on the size of the switch element SW when the loop switching unit 80 having the switch element SW or the like is employed. The resistance when the switch element SW is turned ON changes the amount of induced current, thereby changing the amount of magnetic coupling. The measurement results of an IC actually manufactured as shown in FIG. 5 show that the amount of magnetic coupling decreases by 17 dB.

According to the present invention described above, the conductor loop for shielding the magnetic field, which can reduce the magnetic field coupling between the PA and the oscillator, is disposed over the inductor so that an induced current can flow in the inductor of the oscillator, thereby increasing isolation between the inductors. In general, an inductance of an inductor may be reduced when an induction current is generated in itself, and the performance of the oscillator employing the inductor is deteriorated. Therefore, it is the basis of RFIC design to design such that no induction current can be induced. By creating a pattern similar to the superconductor, isolation degree between the inductors can be improved with minimal performance degradation. In an actual implementation, the conductor loop for it may be made using, for example, aluminum pad metal above the inductors.

In order to prevent deterioration in performance of the inductor, it is preferable to increase the width of the conductor loop to reduce the resistance and to arrange the conductor loop so that a parasitic capacitance is small. The conventional 8-shaped inductor is disadvantageous in that it may not be used for a low power RFIC requiring a large inductor and a large area. However, the inductor layout according to the present invention is advantageous in that it can be used for all inductor values without increasing the area, and the performance is also excellent.

According to the present invention, since the conductor loop for shielding the magnetic coupling is added over the inductors, the amount of magnetic coupling between the inductors can be reduced. Accordingly, while the chips including them can be placed close together, there is no increased area due to addition of the shielding rings. As a manufacturing process technology advances, chip miniaturization is accelerating, and the inductors need to be placed closer together. Thus, the present invention is expected to be widely used in the RFIC industry. Since it is free from magnetic field coupling noise, overall performance improvement can be expected. The present invention can also be applied to devices such as a wireless transmitter, a wireless receiver, etc.

The foregoing is illustrative of example embodiments and is not to be construed as limiting thereof. Although a few example embodiments have been described, those skilled in the art will readily appreciate that many modifications are possible in the example embodiments without materially departing from the novel teachings and advantages of the present disclosure. Accordingly, all such modifications are intended to be included within the scope of the present disclosure as defined in the claims.

What is claimed is:

1. An inductor layout, comprising:
an inductor coil; and
a conductor loop disposed over the inductor coil, and configured to shield magnetic coupling between the inductor coil and a first time-varying magnetic field directed to the inductor coil from a peripheral magnetic field source such that at least a part of magnetic flux of the first time-varying magnetic field is cancelled by magnetic flux of a second magnetic field generated by an induction current that flows in the conductor loop which is magnetically interlinked with the magnetic flux of the first time-varying magnetic field.

2. The inductor layout of claim 1, wherein the conductor loop is disposed so as to surround a circumference of the inductor coil when viewed in a direction normal to the inductor coil.

3. The inductor layout of claim 1, wherein the conductor loop includes a loop switching unit as a part of an entire section of the conductor loop, and wherein the loop switching unit includes a switch element and a resistor, which is connected to the switch element in parallel to each other, configured to block the flow of the induction current, and controls a function of shielding the magnetic coupling by the conductor loop for the inductor coil to be activated or deactivated as the switch element is turned on or off.

4. The inductor layout of claim 1, wherein the conductor loop is made of a conductor pad or a conductor coil being wound a plurality of turns.

5. The inductor layout of claim 1, wherein the inductor coil is a spiral coil or a ring-shaped coil.

6. An integrated circuit device, comprising:
a first inductor coil;
a second inductor coil spaced apart in a horizontal direction around the first inductor coil; and
a conductor loop disposed over the first inductor coil, and configured to shield magnetic coupling between the first inductor coil and the second inductor coil such that at least a part of magnetic flux of a first time-varying magnetic field generated by the second inductor coil is cancelled by magnetic flux of a second magnetic field generated by an induction current that flows in the conductor loop which is magnetically interlinked with the magnetic flux of the first time-varying magnetic field.

7. The integrated circuit device of claim 6, wherein the conductor loop includes a loop switching unit as a part of an entire section of the conductor loop, and wherein the loop switching unit includes a switch element and a resistor, which is connected to the switch element in parallel to each other, configured to block the flow of the induction current, and controls a function of shielding the magnetic coupling by the conductor loop for the inductor coil to be activated or deactivated as the switch element is turned on or off.

8. The integrated circuit device of claim 6, wherein the integrated circuit device is a radio frequency integrated circuit (RFIC) device.

9. The integrated circuit device of claim 8, wherein the first inductor coil is an inductor for a power amplifier, and the second inductor coil is an inductor for an oscillator.
